(19) United States
(12) Patent Application Publication
(10) Pub. No.: US 2006/0011975 A1
(43) Pub. Date: Jan. 19, 2006

(54) Semiconductor device and manufacturing method for the same

(76) Inventors: Hisashi Yonemoto, Fukuyama-shi (JP); Kazushi Naruse, Fukuyama-shi (JP); Hideyuki Ishikawa, Fukuyama-shi (JP); Yasuhiko Okayama, Fukuyama-shi (JP)

Correspondence Address: HARNESS, DICKEY & PIERCE, P.L.C., P.O. BOX 8910, RESTON, VA, 20195, US

(21) Appl. No.: 11/178,458

(22) Filed: Jul. 12, 2005

(30) Foreign Application Priority Data
Jul. 13, 2004 (JP) 2004-206340

(51) Int. Cl. H01L 29/76

(52) U.S. Cl. 257/335

(57) ABSTRACT

A manufacturing method for a semiconductor device, comprising the steps of: (a) forming a body portion of a DMOS by implanting impurity ions of a second conductive type into a predetermined region of a well of a first conductive type that has been formed in a main surface of a semiconductor substrate a plurality of times while changing an implantation amount or an implantation energy or both of them; (b) forming a gate dielectric film on the semiconductor substrate in a gate electrode formation region at least within the well, followed by a gate electrode on the gate dielectric film so as to cross an end of the body portion; (c) forming diffusion layers of the first conductive type on both sides of the gate electrode by implanting impurity ions of the first conductive type (provided that at least one of the diffusion layers is formed within the body portion); and (d) forming a contact layer of the second conductive type by implanting impurities of the second conductive type into the body portion with a impurity concentration higher than the impurity concentration in the body portion.

### CROSS-REFERENCE TO RELATED APPLICATION

This application is related to Japanese application No. 2004-206340 filed on Jul. 13, 2004, the disclosure of which is incorporated by reference in its entirety.

### BACKGROUND OF THE INVENTION

1. Field of the Invention

The invention relates to a semiconductor device and a manufacturing method for the same. In particular, the invention relates to a semiconductor device that includes a DMOS (Laterally Diffused MOS, which is hereinafter referred to as LDMOS, or vertically diffused MOS, which is hereinafter referred to as VDMOS) that can be utilized for a high voltage application such as one for a power supply, and to a manufacturing method for the same.

2. Description of the Related Art

DMOSs are known as one type of high voltage transistors in integrated circuits that include a high voltage circuit such as one for a power supply. A body portion (channel portion) of such a DMOS has conventionally been manufactured in a self-aligning manner. A process according to such a manufacturing method makes it possible to be used together with a manufacturing process for a logic circuit MOS, and therefore, has conventionally been used particularly in the fabrication of a semiconductor device where the logic circuit MOS and the DMOS both exist.

FIGS. 7A to 7E briefly show a manufacturing method for an LDMOS from among conventional DMOSs. First, an N well 411 is formed in a semiconductor substrate (Si substrate) 410 in accordance with a manufacturing procedure that is well known for a CMOS process, and then, a gate dielectric film 440 and a gate electrode 441 are formed (FIG. 7A). In FIG. 7A, 430 indicates a -field oxide film.

Next, an opening is created in a photoresist 420 on the source side, and impurity ions are implanted in the body portion using the end of the gate electrode 441 on the source side as a mask so as to gain a body implantation layer 414, and then, these impurity ions are thermally diffused at a high temperature no lower than 1000° C., and thereby, a body portion 415 is formed (FIGS. 7C and 7D).

At this time, the impurities that extend in the lateral direction as a result of the isotropic diffusion of the impurities form a channel portion of a DMOS (portion A in FIG. 7E) beneath the gate electrode 441 in a self-aligning manner relative to the gate electrode 441.

After that, in accordance with a well known manufacturing procedure, N⁺ diffusion layers 417 and 418 are formed, and a P⁺ contact layer 416 is formed. Furthermore, an interlayer insulating film 460 is formed, and subsequently, metal wires 470 are formed. The LDMOS is manufactured in accordance with the aforementioned process. In FIG. 7E, 442 indicates sidewall spacers, and 491, 492 and 493 indicate a source terminal, a gate terminal and a drain terminal, respectively.

According to a method for forming an LDMOS in a self-aligning manner, which has been conventionally used, however, several problems arise as described below.

(1) A process for driving impurities into an area beneath the gate electrode by means of a heat treatment for a long period of time at a high temperature no lower than 1000° C. is necessary after the impurities have been implanted into the body portion, and therefore, a problem arises where the profile of the implanted impurities becomes uneven as a result of the redistribution due to the heat treatment. In particular, the profile of the impurities that have diffused in the lateral direction relates to the channel region in the portion of the LDMOS, and therefore, the unevenness of the profile due to the thermal diffusion can not be ignored particularly in a microscopic element (which generally has a channel length of no greater than 1.0 μm). As a result, the aforementioned method is a manufacturing method that important properties such as those in terms of a threshold voltage, an on-resistance and the like, tend to become irregular.

FIG. 8 shows a profile of impurities which form a body portion of an N-channel type LDMOS as a result of a thermal diffusion. It is necessary to form the profile in the body portion solely as a result of a diffusion of P-type impurities in the lateral direction. At this time, the impurity concentration of the P-type impurities must be secured in the surface of the substrate so as to be no lower than the impurity concentration of the N-type impurities in the N well (a in the figure). a includes a factor of irregular thermal diffusion, and therefore, it is necessary to control the impurity concentration so that α becomes a large value. In addition, it is necessary to secure a high impurity concentration of the P-type impurities in order to secure a withstand voltage against punch through between the N well and the N⁺ source, and as a result of this, the P-type impurities are diffused so as to have a high impurity concentration, and consequently, the P-type impurity concentration α in the surface of the body portion tends to become high.

Meanwhile, the threshold value Vth of the LDMOS increases when α increases, and both in the saturated region and in the linear region, drive current Id of the LDMOS, which is represented by the following equation (1) in the saturated region and represented by the following equation (2) in the linear region, must decrease as the value of Vgs−Vth (Vgs: gate voltage) decreases.

$$\begin{matrix}Id = \frac{1}{2} {β ( Vgs - Vth )}^{2} provided that β = \frac{W}{L} μ eff \cdot Cox & ( 1 ) \\ Id = β ( Vgs - Vth ) Vds - \frac{1}{2} {Vds}^{2} \} ( Vds \text{:} drain voltage ) & ( 2 )\end{matrix}$$

Therefore it is theoretically difficult to gain a large drive current, that is to say, to form an LDMOS of which the on-resistance is small. Specifically it is difficult to set the Vth at a value of no greater than 1.0 V for an LDMOS of which the channel length is no greater than 1.0 μm.

(2) In a self-aligning system, the implantation energy is restricted by the thickness of the gate electrode which becomes a mask at the time of implantation in a body portion, and therefore, formation of a profile in the depth of direction is limited.

(3) According to a method for forming a body portion of an LDMOS through thermal diffusion at the time of the fabrication of an existing logic circuit MOS and an LDMOS, the properties of the existing logic circuit MOS fluctuate in the step of thermal diffusion, and therefore, it becomes necessary to adjust the properties of the logic circuit MOS or to re-design the designed circuit.

(4) In order to prevent the properties of the logic circuit MOS from fluctuating in the aforementioned (3), it is necessary to form the gate electrodes of the LDMOS and the logic circuit MOS in different steps, causing the number of steps to increase.

These problems (3) and (4) are illustrated in FIGS. 9A and 9B. In the case where, after implantation into a body portion of an LDMOS and implantation for adjusting the threshold value of a logic circuit MOS have been carried out, gate electrodes 414 of the two MOSs are formed at the same time (FIG. 9A), and after that, thermal diffusion is carried out for forming a body portion of the LDMOS, and then, the impurities that have already been implanted in order to adjust the threshold value of the logic circuit MOS diffuse and cause the properties, such as the threshold value to fluctuate (FIG. 9B). In order to avoid the fluctuation in the properties of the logic circuit MOS, it is necessary to implant impurities for adjusting the threshold value of the logic circuit MOS and to form the gate electrode after heat treatment has been carried out for the formation of the gate electrode and the formation of the body portion in the LDMOS portion, and therefore, the number of steps increases. In FIGS. 9A and 9B, 450 and 451 indicate implantation layers, and 452 indicates a portion of which the properties have fluctuated.

A manufacturing method by Motorola (Japanese Unexamined Patent Publication No. HEI 11(1999)-354793) can be cited as a method for avoiding problems (1) and (2) (FIGS. 10A to 10D). According to this method, a dielectric layer 453 of which the thickness is different from that of the gate electrode is provided instead of the gate electrode and is used as a mask in the formation of a body portion 415 in a self aligning manner the body portion 415 is formed, and after that, a gate electrode 441 is formed. According to this method, however, a manufacturing method is used so as to include self alignment and thermal diffusion and therefore, the aforementioned problems (1) and (2) cannot be completely solved.

### SUMMARY OF THE INVENTION

The invention provides a manufacturing method for a semiconductor device, comprising the steps of:

(a) forming a body portion of a DMOS by implanting impurity ions of a second conductive type into a predetermined region of a well of a first conductive type that has been formed in a main surface of a semiconductor substrate a plurality of times while changing an implantation amount or an implantation energy or both of them;

(b) forming a gate dielectric film on the semiconductor substrate in a gate electrode formation region at least within the well, followed by forming a gate electrode on the gate dielectric film so as to cross an end of the body portion;

(c) forming diffusion layers of the first conductive type on both sides of the gate electrode by implanting impurity ions of the first conductive type, provided that at least one of the diffusion layers is formed within the body portion; and

(d) forming a contact layer of the second conductive type by implanting impurities of the second conductive type into the body portion with an impurity concentration higher than the impurity concentration in the body portion.

The invention also provides a semiconductor device comprising:

a body portion of a DMOS of a second conductive type which is formed in a predetermined region of a well of a first conductive type that is formed in a main surface of a semiconductor substrate;

a gate dielectric film which is formed on the semiconductor substrate;

a gate electrode which is formed on the gate dielectric film so as to cross an end of the body portion;

diffusion layers of the first conductive type which are formed in the main surface of the semiconductor substrate on both sides of the gate electrode, provided that at least one of the diffusion layers is formed within the body portion;

a contact layer of the second conductive type which is formed within the body portion and of which the impurity concentration is higher than that of the body portion; and

the body portion including a region where the difference in the impurity concentration between the body portion and the well in the depth direction is greater than the difference in the impurity concentration between the body portion and the well in the surface of the semiconductor substrate.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a conceptual diagram showing the impurity concentration profile of the body portion of an N type LDMOS according to the invention;

FIGS. 2A to 2C are schematic cross sectional views showing DMOSs according to the invention;

FIGS. 3A and 3B are schematic cross sectional views showing a DMOS according to the invention;

FIGS. 4A to 4M′ are cross sectional views schematically illustrating the steps in the fabrication of a DMOS according to the invention;

FIGS. 5A to 5C are cross sectional views schematically showing the steps in the Simultaneous formation of a DMOS according to the invention and a logic circuit MOS;

FIGS. 6A to 6H′ are cross sectional views schematically illustrating the steps in the fabrication of a DMOS according to the invention;

FIGS. 7A to 7E are cross sectional views schematically illustrating the steps in the fabrication of an LDMOS according to the prior art;

FIG. 8 is a conceptual diagram showing the impurity concentration profile of the body portion of N type LDMOS according to the prior art;

FIGS. 9A and 9B are cross sectional views schematically showing the steps in the simultaneous formation of a DMOS according to the prior art and a logic circuit MOS; and

FIGS. 10A and 10D are cross sectional views schematically showing the steps in the simultaneous formation of a DMOS according to the prior art and a logic circuit MOS.

### DETAILED DESCRIPTION OF THE INVENTION

In the following, a semiconductor device according to the invention is described.

First, a well of a first conductive type is formed in the main surface of a semiconductor substrate and a body portion of a DMOS of a second conductive type is formed in a predetermined region of this well of the first conductive type.

Here, the semiconductor substrate is not particularly limited as long as it is utilized for a semiconductor device and bulk substrates made of element semiconductors such as silicon or germanium, or compound semiconductors such as silicon germanium, GaAs, InGaAs, ZnSe, or GaN can be cited as examples. In addition, a variety of substrates such as an SOI (Silicon On Insulator) substrate, an SOS substrate and a multilayered SOI substrate, as well as glass or plastic substrates having a semiconductor layer formed thereon may be used as the substrate having a semiconductor layer on the surface. From among these, a silicon substrate and an SOI substrate where a silicon layer is formed on the surface are preferable. The semiconductor substrate or the semiconductor layer may be any of single crystal (for example, epitaxially grown crystal), polycrystal and amorphous, though the amount of current that flows inside may slightly differ.

Next, the well and the body portion have the first conductive type and the second conductive type, respectively. The first conductive type is either p type or n type and the second conductive type is a conductive type that is opposite to the first conductive type. In the case where the semiconductor substrate is a silicon substrate, boron can be cited as an impurity which provides p type and phosphorus, arsenic, and the like can be cited as an impurity which provides n type.

In addition, the body portion is provided with a region where the difference in the impurity concentration between the body portion and the well in the direction of the depth is greater than the difference in the impurity concentration between the body portion and the well in the surface of the semiconductor substrate (for example, no less than 1.5 times, preferably 2 to 10 times when Vth is 0.7 V). By providing this region, the DMOS of which the on-resistance is small and where a high withstand voltage is secured can be gained with high precision.

The impurity concentration of the body portion is set at a value that corresponds to the threshold value (for example, no greater than E17/cm³) on the semiconductor surface side, while a impurity concentration region that can secure a withstand voltage between the N⁺ diffusion region of the source and the N well (for example, 1E17/cm³ to 5E18/cm³, the width of the diffusion in the body beneath N⁺ diffusion of 0.6 μm to 1.5 μm) is provided in a deep position, and these impurity concentrations can be individually controlled.

As a result, the impurity concentration of a portion that is required to secure a high withstand voltage in the direction of the depth and is approximately 1 to 10 times greater of the impurity concentration of the surface, and the body can be formed so as to have a depth of approximately 0.7 μm to 2 μm.

Here, advantages in forming the body through implantations in multiple stages, where no drives are utilized, can be cited as follows; (1) it becomes easy to design the body because the body can be formed so as to become shallower and have a higher impurity concentration, and (2) it becomes possible to reduce the length of the channel.

The depth of the body portion can be appropriately changed in accordance with the performance of the semiconductor device and is usually approximately 0.7 μm to 2 μm. Meanwhile, the depth of the well is usually approximately 2 μm to 8 μm.

Here, the setting of the impurity concentration of the body affects the withstand voltage of the LDMOS and the resistance of the body portion affects the on-withstand voltage. According to the invention, implantation of the ions for determining the threshold value in the surface and implantation of ions for determining the withstand voltage can be separately controlled, and therefore, this is advantageous in designing the body.

In addition, the width of the body portion can be set in accordance with the length of the channel of a desired DMOS and is, for example, approximately 2.2 μm to 3 μm. Furthermore, it is possible to form a channel length of, for example, 0.2 μm to 0.5 μm because the process does not require a drive through diffusion.

Though the width of the well is not particularly limited as long as it does not hinder the functions of the DMOS, it is preferable for the width to include the body portion, the diffusion layer, the contact layer and the region beneath the gate electrode.

Furthermore, a gate dielectric film is provided on the semiconductor substrate and a gate electrode is formed on the gate dielectric film so as to cross an end of the body portion.

The gate dielectric film is not particularly limited as long as it is of a type that is usually utilized for a semiconductor device, and a single layer film, or a layered film, of an insulating film, such as a silicon oxide film or a silicon nitrate film and/or a high dielectric film, such as an aluminum oxide film, a titanium oxide film, a tantalum oxide film or a hafnium oxide film, for example, can be utilized. From among these, a silicon oxide film is preferable. It is appropriate for the gate dielectric film to have a film thickness (calculated as being converted to a gate oxide film) of approximately 2 nm to 14 nm, preferably a film thickness of approximately 4 nm to 9 nm. The gate dielectric film may be formed only directly beneath the gate electrode, or may be formed so as to be greater (wider) than the gate electrode.

The gate electrode is formed on the gate dielectric film so as to cross an end of the body portion. The gate electrode is not particularly limited as long as it is of a type that is usually utilized for a semiconductor device, and conductive films, single layer films and layered films made of polysilicon, a metal such as copper or aluminum, a high melting point metal such as tungsten, titanium or tantalum, or a silicide with a high melting point metal can be cited as examples.

It is appropriate for the film thickness of the gate electrode to be, for example, approximately 90 nm to 300 nm.

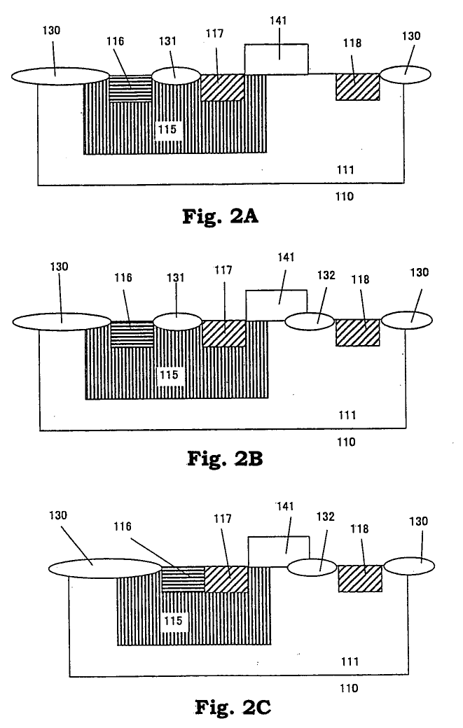

Furthermore, diffusion layers of the first conductive type are provided in the main surface of the semiconductor substrate on both sides of the gate electron. It is preferable for the impurity concentration of the impurities in the diffusion layers to be in a range from approximately 1E19/cm³ to 5E20/cm³. In addition, at least one of the diffusion layers is formed within the body portion. The diffusion layers may be aligned with the two ends of the gate electrode, or may be offset to one or two diffusion layers 117 and/or 118, as shown in FIG. 2A. Furthermore, as shown in FIGS. 2B and 2C, an isolation film 132 is formed at an end of the gate electrode 141, and thereby, the diffusion layer 118 may be isolated.

In FIGS. 2A to 2C, 110 indicates a semiconductor substrate, 111 indicates a well, 115 indicates a body portion, 116 indicates a contact layer, 117 and 118 indicate diffusion layers, 1-30 indicates a field oxide film, 131 and 132 indicate isolation films and 141 indicates a gate electrode.

In the case of the LDMOS, the diffusion layers correspond to the source and the drain. In addition, in the case of a VDMOS, the diffusion layer corresponds to one of the source and the drain and the drain or the source which does not correspond to the diffusion layer is usually provided on the rear surface of the semiconductor substrate.

In addition, a contact layer of the second conductive type of which the impurity concentration is higher than that of the body portion is provided with in the body portion. In the case where the impurity concentration is not high, an ohmic junction is not formed, the contact resistance becomes high and the on-withstand voltage is lowered and thus this is not preferable. In addition, it is preferable for the impurity concentration of the contact layer to be 100 times higher or more, than the impurity concentration of the body portion, and it is more preferable for the impurity concentration of the contact layer to be 500 to 1000 times higher than the impurity concentration of the body portion.

The diffusion layer 117 and the contact layer 116 which are formed within the body portion may make contact with each other as shown in FIG. 2C or may not make contact with each other as shown in FIGS. 2A and 2B. In FIGS. 2A and 2B, the isolation film 131 is formed between the diffusion layer 117 and the contact layer 116 and thereby the two layers are separated from each other. Here, in FIGS. 2A and 2B, the diffusion layer 117 is used as the source and the diffusion layer 118 is used as the drain.

The specific structure of the semiconductor device according to the invention is not particularly limited as long as it has the aforementioned configuration. It is, for example, applicable to the LDMOS or the VDMOS.

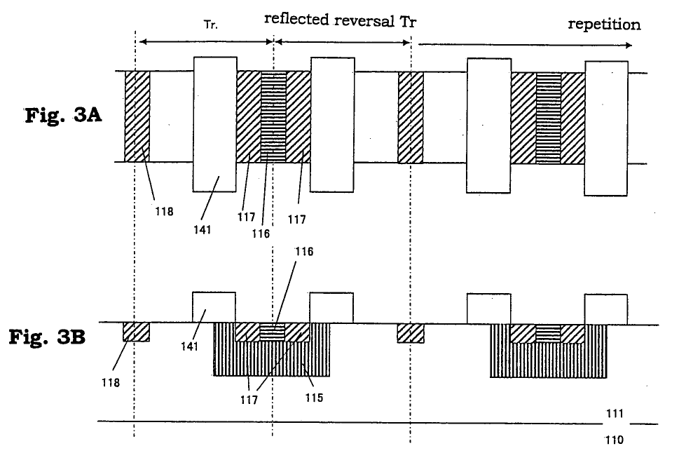

A plurality of DMOSs, which are the same as the aforementioned DMOSs, may be aligned in parallel on the semiconductor substrate. The manner of parallel alignment is not particularly limited but a known form can be adopted. Within such an alignment, as shown in, for example, FIGS. 3A and 3B, LDMOSs in the configuration may be aligned in a reverse manner as like a mirror with the contact layer 116 and the diffusion layer 118 being the center. In this configuration, adjacent LDMOSs can share the contact layer 116 and the diffusion layer 118, and thereby, the area occupied by the LDMOSs can be reduced.

Next, a manufacturing method for the semiconductor device according to the invention is described.

First, impurity ions of a second conductive type are implanted into a predetermined region of a well of a first conductive type that has been formed in the main surface of a semiconductor substrate a plurality of times while changing the implantation amount, the implantation energy, or both of them, and thereby, the body portion of a DMOS is formed (step (a)).

The number of times of the implantation is set in accordance with the depth of the body portion that is desired to be formed. Namely, in the case where the depth is great, the number is great and in the case where the depth is shallow, the number is small. For example, in the case where the depth of the body portion is in a range from 0.8 μm to 1.0 μm, it is preferred that the implantation is separately carried out for about three times.

Here, it is preferable to implant impurity ions starting from the deeper side and from the point of view of reduction of the dispersion in the depth of the implantation due to channeling. Accordingly, it is preferable for the implantation energy to be reduced step by step.

In addition, it is desirable to set the implantation amount in a manner where the implantation into a middle portion does not cause a leak to occur between the source and the drain in the case where the body portion is desired to be provided with a region in a deep portion of which the impurity concentration is no lower than that in the surface of the semiconductor substrate. The leak results from a drop in the impurity concentration in the implantation profile ranging from the surface to the deep portion. It is preferable for the implantation amount into the middle to be, for example, approximately 0.5 to 1 times smaller than the implantation amount into the first and the last portions.

Specifically, in the case where the impurity ions are boron ions, it is preferable to carry out three times implantation of 2 to 5 E13 ions/cm² with 130 KeV to 160 KeV, 3 to 8 E12 ions/cm² with 60 KeV to 80 KeV, and 2 to 6 E12 ions/cm² with 20 KeV to 30 KeV.

In addition, depending on the setting of the withstand voltage, in some cases, further the implantation of a low impurity concentration is added to a region beneath the region of a high impurity concentration, and the electrical field of the N junction portion between the body and the N well may be relieved.

In particular, ion implantation into the middle portion is carried out in order to avoid a drop in the implantation profile between the two implantation regions (a region of an extremely impurity concentration of N− or P− (up to E16/cm³)) in the case where the implantation for controlling Vth and the implantation for securing a withstand voltage are carried out while controlling the two separately. As a result of this implantation, the leak current between the source and the drain can be reduced.

In this step (a), the aforementioned predetermined region is defined with one photomask, and it is preferable to implant impurity ions of the second conductive type a plurality of times (at least two or more times) using this photomask, and in addition, to carry out an annealing process. By defining the area with one photomask, the step of forming a photomask can be omitted. In addition, it is preferable for the temperature for annealing at this time to be 750° C. to 900° C.

Next, a gate dielectric film is formed on a semiconductor substrate in the gate electrode formation region, at least within the well, and a gate electrode is formed on the gate dielectric film so as to cross an end of the body portion (step (b)).

An appropriate method for forming the gate dielectric film can be selected in accordance with the type thereof. A thermal oxidation method, a CVD method, a deposition method, a sol-gel method and the like can be cited as examples. An appropriate method for forming the gate electrode can be selected in accordance with the type thereof. A CVD method, a deposition method, a sol-gel method and the like can be cited as examples.

Next, diffusion layers of the first conductive type are formed in the surface layers of the well and the body portion on both sides of the gate electrode through the implantation of impurity ions of the first conductive type (step (c)).

As for specific implantation conditions, in the case where impurity ions are phosphorous ions, it is preferable for the implantation energy to be 15 KeV to 20 KeV, and the implantation amount to be 5E+14 ions/cm² to 5E+15 ions/cm².

Finally, a contact layer of the second conductive type is formed by implanting impurities of the second conductive type into the body portion, so that the impurity concentration thereof becomes higher than the impurity concentration in the body portion (step (d)).

As for specific implantation conditions, in the case where impurity ions are boron ions, it is preferable for the implantation energy to be 10 KeV to 20 KeV, and the implantation amount to be 5E+14 ions/cm² to 5E+15 ions/cm².

An annealing process may be carried out after the step (c) and before the step (d), and thereby, an annealing process may be carried out simultaneously on the body portion and the diffusion layers. It is preferable for the temperature for annealing at this time to be in a range from 700° C. to 900° C.

Here, in the case of an LDMOS, the diffusion layers correspond to the source and the drain. Meanwhile, in the case of a VDMOS, the diffusion layer corresponds to one of the source and the drain, and the drain or the source which is not the diffusion layer is formed in the rear surface of the semiconductor substrate.

Furthermore, the manufacturing method according to the invention can be applied to the fabrication of a semiconductor device where a MOS transistor for a logic circuit and/or a withstand voltage MOS transistor and a DMOS are both provided.

Specifically, in the case where the semiconductor device is further provided with a MOS transistor for a logic circuit that is formed within the well of the second conductive type on a semiconductor substrate having a DMOS, the aforementioned well of the second conductive type can be formed at the same time as the aforementioned body portion. In addition, in the case where the semiconductor device is further provided with a diffusion layer for relieving the electrical field of the source or the drain of the second conductive type and a withstand voltage MOS transistor having a channel of the second conductive type, the aforementioned body portion can be formed at the same time as the diffusion layer for relieving the electrical field of the source or the drain of the aforementioned MOS transistor. As a result of the simultaneous formation, the number of steps in the fabrication of a semiconductor device can be reduced.

Here, the MOS transistor for a logic circuit and the withstand voltage MOS transistor are not particularly limited, and any well-known configuration can be adopted. A configuration where the source and the drain are provided in a well of the second conductive type and a gate electrode is provided on the semiconductor substrate between the source and the drain via a gate dielectric film, for example, can be cited as a MOS transistor for a logic circuit. The source and the drain may have an LDD structure.

A withstand voltage MOS transistor may be provided with approximately the same configuration as that of the aforementioned MOS transistor for a logic circuit, but the gate electrode and the source and/or drain are offset.

Furthermore, diffusion layers for relieving the electrical field of the source and/or drain of the second conductive type are formed in the surface layer of the offset semiconductor substrate.

The semiconductor device according to the invention can be utilized for high withstand voltage application, for example, for power supplies, and specifically, can be utilized for output transistors, switching transistors and the like, from among the aforementioned applications.

### EMBODIMENTS

In the following, the invention is described in further detail in reference to the embodiments.

In the following embodiments, though N channel type LDMOS and VDMOS are cited, the invention is not limited to the N channel type LDMOS and VDMOS, and similar implementations are, or course, possible for P channel type LDMOS and VDMOS.

First Embodiment

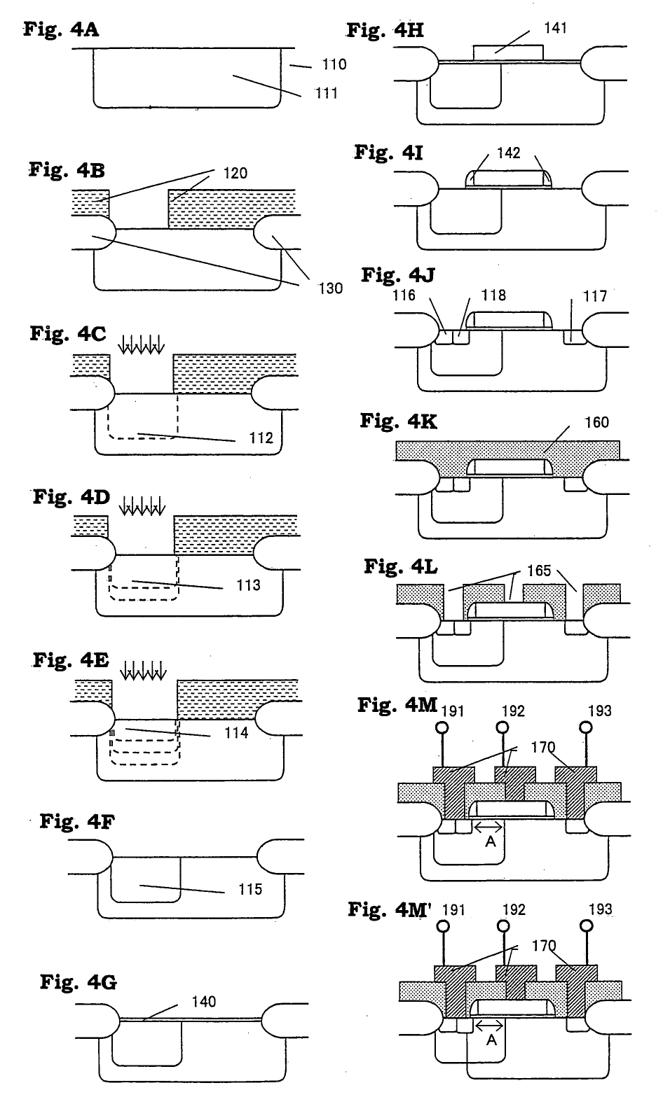

FIGS. 4A to 4M are cross sectional views schematically illustrating the steps in the fabrication of a semiconductor device according to a first embodiment.

Step (a)

First, as shown in FIG. 4A, ³¹p⁺ ions are implanted into a well formation region in a semiconductor substrate (Si substrate) 110, with an implantation amount of 1E13 ions/cm² and an energy. of 400 KeV, and heat treatment at 1150° C. is carried out for 6 hours, so as to form an N well 111 having Xj up to 4 μm and a impurity concentration of 2E16/cm³.

After that, a SiNx film is deposited, and the SiNx film is removed using a photoresist having an opening in an element isolation region. Next, the SiNx film is used as an oxide protective film in the transistor region, and a thermal oxidation process is carried out at 1050° C. for 2 hours, so as to form a thermal oxide film (field oxide film 130) of approximately 600 nm in the element isolation region. After this, the SiNx film is removed from the entirety of the surface. Here, the order of the steps in the well formation and the field oxide formation may be switched without causing any problems.

Next, a photoresist 120 having an opening is provided in a region of the semiconductor substrate 110 where a body portion 115 is formed (FIG. 4B).

Next, as shown in FIGS. 4C to 4E, P type impurity ions are implanted a plurality of times, in order to form the body portion 115. In FIGS. 4 C to 4E, 112 to 114 indicate the first to third body implantation layers.

According to the first embodiment, ion implantation of ion species ¹¹B⁺ is carried out three times in total, with an implantation amount of 1 to 5E13 ions/cm² and an energy of 150 KeV, with an implantation amount of 5E12 ions/cm² and an energy of 100 KeV, and with an implantation amount of 1E12 ions/cm² and an energy of 30 KeV.

Next, as shown in FIG. 4F, an annealing process is carried out at 750° C. for 30 minutes, in order to activate impurities in the substrate, and thereby, the body portion 115 is formed. At this time, heat treatment is carried out at a temperature of no higher than 1000° C., desirably, at a temperature from approximately 700° C. to 900° C., in order to prevent diffusion of the impurities, and therefore, the region where the body portion is formed is not affected by the thermal diffusion, and as a result, the channel length of the LDMOS can be controlled with high precision.

In addition, it is possible to carry out this annealing process also as annealing for activating the impurities after the below described source/drain implantation. In the case where the annealing process is carried out in this manner, one annealing step can be omitted.

Step (b)

After this annealing process, as shown in FIG. 4G, a gate dielectric film 140 of the LDMOS is formed so as to have a thickness of approximately 5 nm, in accordance with a method for forming a conventional MOS type transistor.

After this, as shown in FIG. 4H, a gate electrode 141 is formed.

Next, as shown in FIG. 41, sidewall spacers 142 are formed on the sidewalls of the gate electrode.

Step (c)

Next, as shown in FIG. 4J, N⁺ diffusion layers (source and drain) 117 and 118 are formed.

Step (d)

Next, a P⁺ contact layer 116 of which the surface impurity concentration is approximately ˜1E20/cm³ and of which the depth Xj is approximately 0.1 μm to 0.2 μm is formed.

After that, as shown in FIG. 4K, a layered film of an oxide film of 100 nm and a BPSG film of 1 μm is formed as an interlayer insulating film 160. Next, heat treatment is carried out at 900° C. for 10 minutes, so that the ions implanted in the source and the drain are activated, and the BPSG film is flattened as a result of reflow.

Next, contact holes 165 are created (FIG. 4L).

Next, metal wires 170 are formed. After that, an interlayer insulating film, a source terminal 191, a gate terminal 192, a drain terminal 193 and the like are formed in predetermined formation steps, and thus, the LDMOS is formed (FIG. 4M).

As shown in FIG. 4M, the length of portion A is the channel length of the LDMOS. Portion A is not affected very much by the thermal diffusion, and therefore, controlling the channel length with high precision, in addition to controlling the threshold value, is possible.

Second Embodiment

The second embodiment provides a structure where a body portion is formed in an N well which becomes a drain region. The body portion may be formed in a P well, as shown in FIG. 4M′, in addition to the aforementioned structure.

Third Embodiment

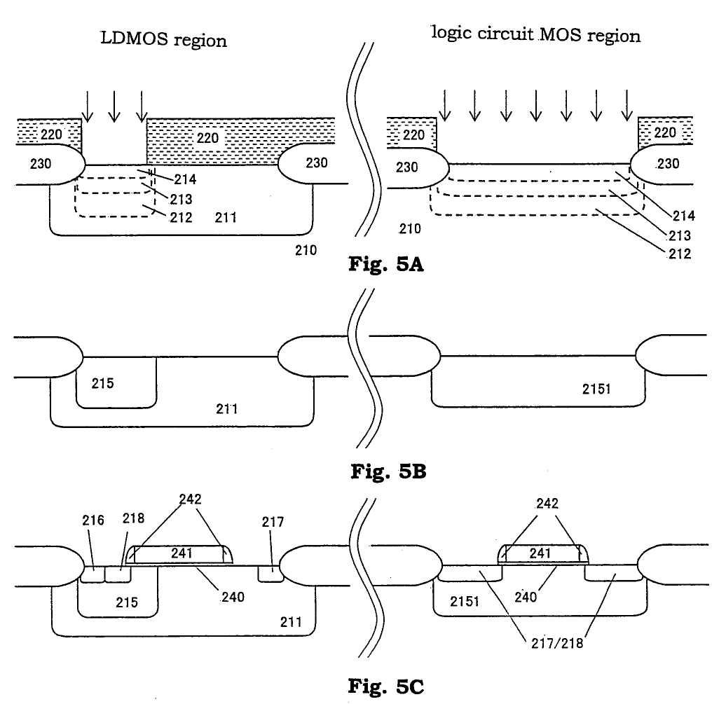

FIGS. 5A to 5C are cross sectional views schematically illustrating the simultaneous formation of a MOS for a logic circuit and an LDMOS.

Step (a)

In FIG. 5A, an opening is provided in a photoresist 220 which determines an implantation region for forming a body portion 215 of the LDMOS, and at the same time, an opening is provided in the photoresist 220, in a portion that becomes a P well 2151 of the MOS for a logic circuit, and then, impurities are implanted. In FIG. 5A, 210 indicates a semiconductor substrate, 211 indicates an N well, 212 to 214 indicate the first to third body implantation layers, respectively, and 230 indicates a field oxide film.

In the aforementioned step, the mask that is utilized for the formation of the first to third body implantation layers 211 to 213 of the LDMOS can also be used as a mask for the formation of a P well of the MOS for a logic circuit, and thereby, the cost of the masks can be reduced, and the number of steps can be reduced.

After that, the P well 2151 of the MOS for a logic circuit and the body portion 215 of the LDMOS are formed in accordance with an annealing process (FIG. 5B).

Steps (b) to (d)

Next, a gate dielectric film 240, a gate electrode 241, sidewall spacers 242, N⁺ diffusion layers (source and drain) 217 and 218 and a contact layer 216 are formed (FIG. 5C).

As a result of the aforementioned steps, a semiconductor device having a MOS for a logic circuit and an LDMOS can be formed.

Here, an LDD (Light Dose Diffusion) step which is utilized in a conventional method for forming a CMOS, can, of course, be added after the formation of the gate electrode.

Fourth Embodiment

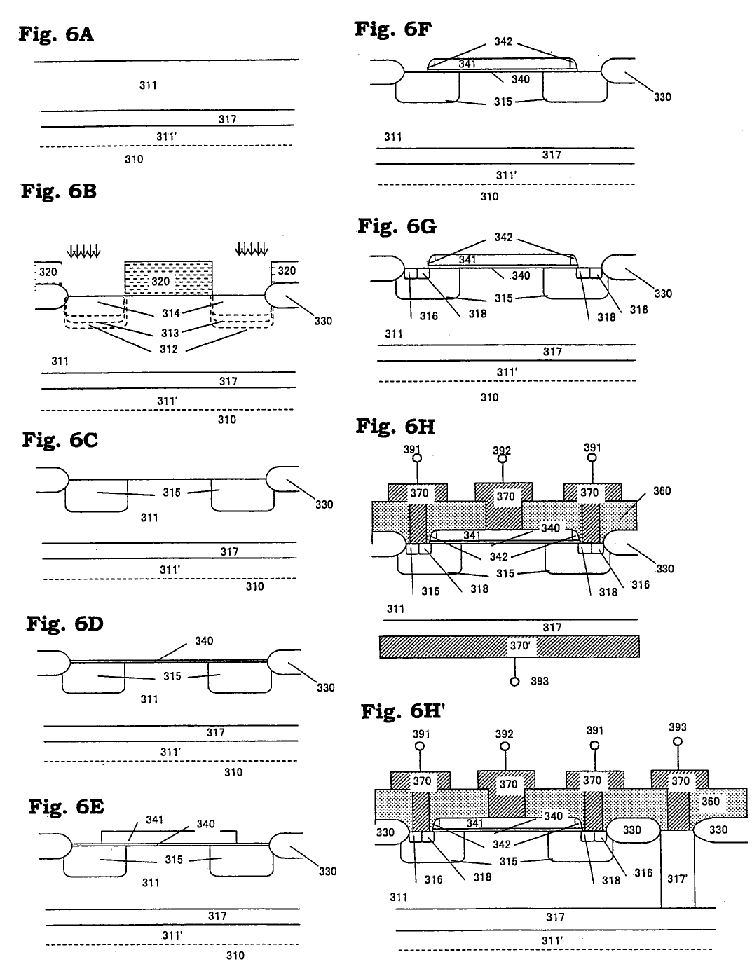

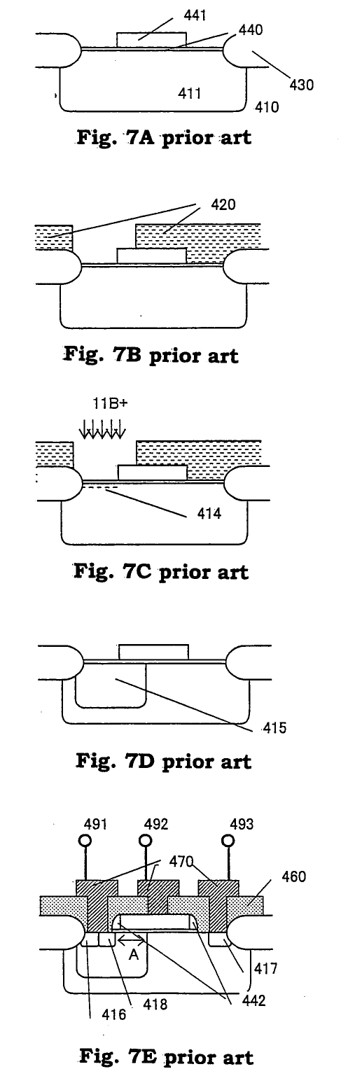

FIGS. 6A to 6H are cross sectional views schematically illustrating the steps in the fabrication of a semiconductor device according to a fourth embodiment.

Step (a)

First, ³¹p⁺ ions are implanted into a well formation region of a semiconductor substrate (Si substrate) 310, with an implantation amount of 1E13 ions/cm² and an energy of 180 KeV, and then, heat treatment is carried out at 1200° C. for 3 hours, so as to form an N well 311′ having Xj of up to 4 μm, and a impurity concentration 2E16/cm³. After that, an N type dopant is diffused in the solid so as to form a buried N⁺ diffusion layer (drain) 317 having an impurity concentration of up to 1E20/cm³ and a depth Xj of up to 1 μm. On top of this, an epitaxially grown film where phosphorous has been doped into Si is deposited so as to have a thickness of 4 μm, and thus, an N type epitaxial film 311 having a impurity concentration of up to 2E16/cm³ is formed (FIG. 6A).

After that, a SiNx film is deposited, and the SiNx film is removed using a photoresist having an opening in an element isolation region. Next, the SiNx film is used as an oxide protective film in the transistor region, and a thermal oxidation process is carried out at 1050° C. for 2 hours, so as to form a thermal oxide film (field oxide film 330) of approximately 600 nm in the element isolation region. After this, the SiNx film is removed from the entirety of the surface.

Next, a photoresist 320 having an opening is provided on the semiconductor substrate 310, in a region where a body portion 315 is formed. Furthermore, P type impurity ions are implanted a plurality of times, in order to form the body portion 315. In FIG. 6B, 312 to 314 indicate the first to third body implantation layers, respectively.

According to the fourth embodiment, ion species ¹¹B⁺ is implanted three times in total, with an implantation amount of 1 to 5E13 ions/cm² and an energy of 150 KeV, with an implantation amount of 5E12 ions/cm² and an energy of 100 KeV, and with an implantation amount of 1E12 ions/cm² and an energy of 30 KeV (FIG. 6B).

Next, as shown in FIG. 6C, an annealing process is carried out at 750° C. for 30 minutes, in order to activate impurities in the substrate, and thereby, the body portion 315 is formed. At this time, heat treatment is carried out at a temperature of no higher than 1000° C., desirably, at a temperature from approximately 700° C. to 900° C., in order to prevent diffusion of the impurities, and therefore, the region where the body portion is formed is not affected by the thermal diffusion, and as a result, the length of the channel of a VDMOS can be controlled with high precision.

In addition, it is possible to carry out this annealing process also as annealing for activating the impurities for the formation of the diffusion layers. In the case where the annealing is carried out in this manner, one annealing step can be omitted.

Step (b)

After this annealing process, as shown in FIG. 6D, a gate dielectric film 340 of the VDMOS is formed so as to have a thickness of approximately 5 nm, in accordance with a method for forming a conventional MOS type transistor.

After that, as shown in FIG. 6E, a gate electrode 341 is formed.

Next, as shown in FIG. 6F, sidewall spacers 342 are formed on the sidewalls of the gate electrode.

Step (c)

Next, as shown in FIG. 6G, a diffusion layer (source) 318 of which the surface impurity concentration is approximately ˜1E20/cm³ and the depth Xj approximately 0.1 μm to 0.2 μm is formed.

Step (d)

Next, a P⁺ contact layer 316 of which the surface impurity concentration is approximately ˜1E20/cm³ and the depth Xj approximately 0.1 μm to 0.2 μm is formed.

After that, as shown in FIG. 6H, a layered film of an oxide film of 100 nm and a BPSG film of 1 μm is formed as an interlayer insulating film 360. Next, the diffusion layer (source) 318 is activated by means of heat processing at 900° C. for 10 minutes, and the BPSG film is flattened as a result of reflow.

Next, metal wires 370 are formed. Subsequently, the rear surface of the semiconductor substrate 310 is polished, and thereby, the buried N⁺ diffusion layer 317 is exposed, so as to form an electrode 370′ on the rear surface of the semiconductor substrate. After that, a source terminal 391, a gate terminal 392, a drain terminal 393 and the like are formed in predetermined steps, and then, the VDMOS is formed (FIG. 6H).

Fifth Embodiment

FIG. 6H′ shows an embodiment in the case where a drain is led out from the surface side of the Si substrate, and the N⁺ diffusion layer 317′ for leading out the N⁺ diffusion layer 317 is formed in the N type epitaxial film 311. The N⁺ diffusion layer 317′ is formed so as to have an impurity concentration of no less than 1E 19/cm³.

A body portion of a DMOS is formed through ion implantations in multiple stages and thereby a sufficiently deep profile can be implemented in order to achieve a high withstand voltage between the source and the drain, and therefore, the number of the driving in step through heat treatment can be minimized. As the result it becomes possible to provide a profile which is not uneven and to control the length of the channel. At this time, the amount of heat treatment is minimal, and therefore, the properties of the logic circuit MOS are not fluctuated even in the case where a DMOS is formed at the same time as an existing logic circuit MOS.

In addition, adjustment of the withstand voltage, by means of a deep ion implantation and control of the threshold voltage by means of a shallow ion implantation can be carried out independently of each other, and therefore, it becomes possible to control the threshold voltage with high precision while securing a sufficient withstand voltage.

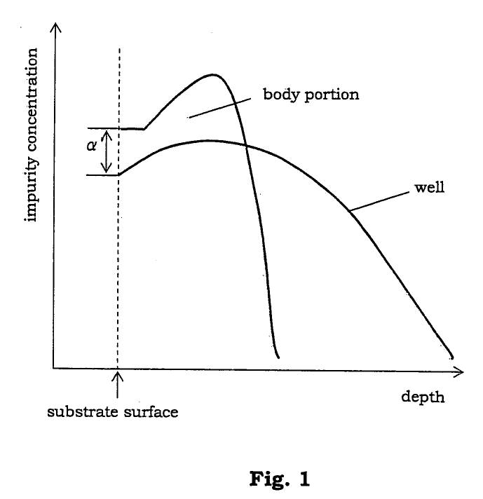

Furthermore, according to a conventional technology by means of thermal diffusion, implantation of a high impurity concentration is necessary in order to gain a deep profile that is required for securing a withstand voltage. According to the invention, a deep profile is gained with a small ion dose as shown in FIG. 1 and therefore, properties having a small number of defects and a small amount of leakage can be gained.

Furthermore, processes for photolithography and ion implantation for controlling the threshold voltage, which are conventionally required, become unnecessary and it becomes possible to reduce the cost.

In addition, a mask is shared for the formation of a well for the logic circuit MOS and for controlling the threshold voltage, and thereby, a semiconductor device where the logic circuit MOS and the DMOS coexist can be implemented without using an additional mask.

Furthermore, a diffusion layer for relieving the electrical field of a source/drain portion of a high voltage MOS and a body portion formed at the same time and thereby a semiconductor device where the high voltage MOS also coexists can be implemented.

Here, it becomes possible to share the processes for the fabrication of an N channel type DMOS and for the fabrication of an N channel type existing logic circuit MOS and/or a P channel type high voltage MOS as well as to share the processes for the fabrication of a P channel type DMOS and for the fabrication of a P channel type existing logic circuit MOS and/or an N channel type high voltage MOS.

In addition, simplification of the process can be implemented by sharing annealing for activating the body portion in the DMOS and annealing for activating the diffusion layer.

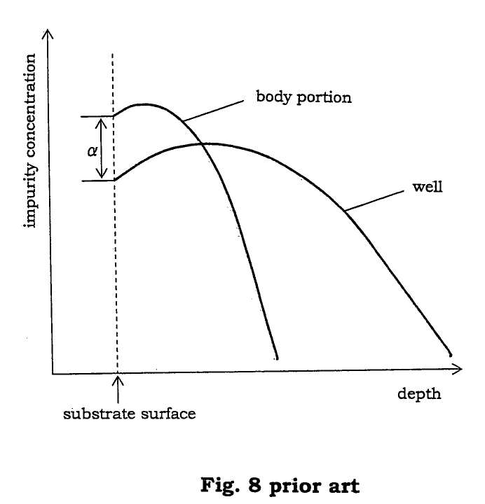

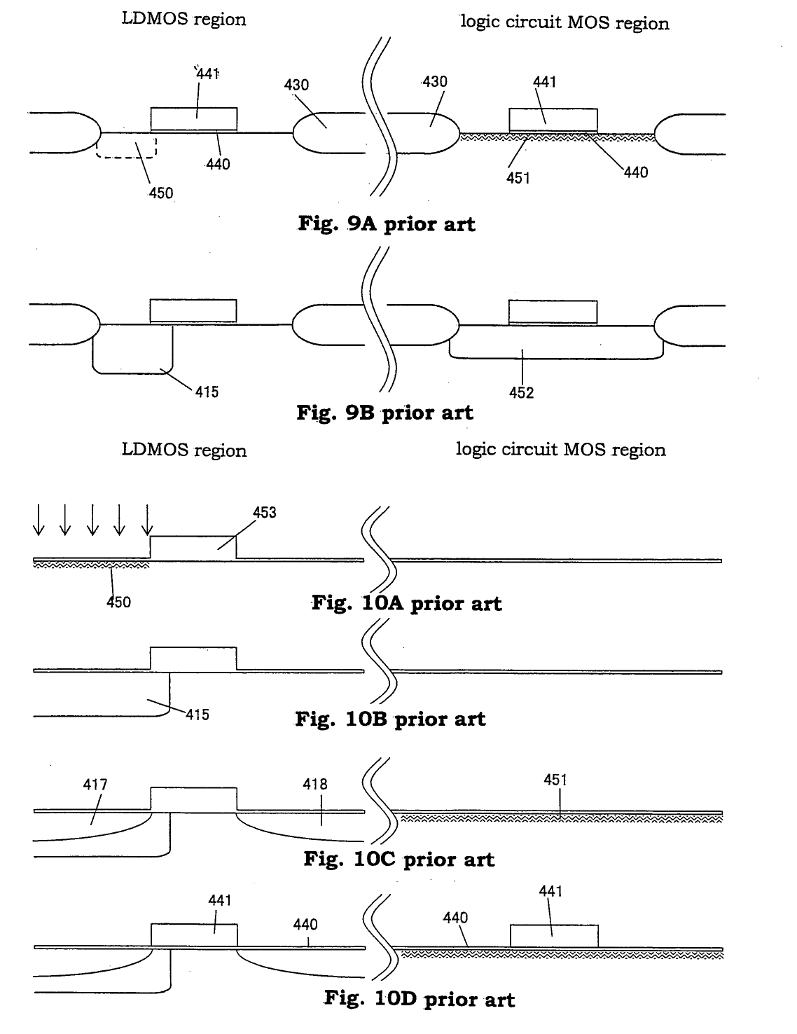

As described above, according to the invention, as shown in FIG. 1, the dispersion of a can be reduced to less than that of FIG. 8 and the dispersion of Vth can also be reduced, and therefore, it becomes possible to set Vth at a value no greater than 1.0 V, specifically, Vth=0.5 V to 0.7 V. Therefore it becomes possible to manufacture the DMOS of which the on-resistance is small with a high precision. In comparison with the prior art, in the case where the gate voltage is designed so as to be Vgs=3.3 V, for example, in the saturated region, a drive current Id of which the amount is approximately two times greater than that of the prior art (Vth=1.5 V) can be gained from the equation (1) according to the invention (Vth=0.7 V).

In the case where elements having the same drive current are manufactured, the area of the element can be reduced approximately by ½ and it becomes possible to greatly reduce the area of the chip. In the linear region (drain voltage Vds=0.1 V), a drive current which is approximately 1.5 times greater than that of the prior art can be gained from the equation (2) according to the invention. In addition it becomes possible to share ion diffusion processes and a mask with a logic circuit MOS that is required for the formation of a semiconductor device and the semiconductor device that includes the DMOS of which the on-resistance is low can be manufactured at a low cost.

What is claimed is:

1. A manufacturing method for a semiconductor device, comprising the steps of:
(a) forming a body portion of a DMOS by implanting impurity ions of a second conductive type into a predetermined region of a well of a first conductive type that has been formed in a main surface of a semiconductor substrate a plurality of times while changing an implantation amount or an implantation energy or both of them;
(b) forming a gate dielectric film on the semiconductor substrate in a gate electrode formation region at least within the well, followed by a gate electrode on the gate dielectric film so as to cross an end of the body portion;
(c) forming diffusion layers of the first conductive type on both sides of the gate electrode by implanting impurity ions of the first conductive type (provided that at least one of the diffusion layers is formed within the body portion); and
(d) forming a contact layer of the second conductive type by implanting impurities of the second conductive type into the body portion with an impurity concentration higher than the impurity concentration in the body portion.

2. The manufacturing method for a semiconductor device according to claim 1, wherein in the step (a), the predetermined region is defined by one photomask, impurity ions of the second conductive type are implanted at least two or more times using the photomask and, further, an annealing process is carried out.

3. The manufacturing method for a semiconductor device according to claim 1, wherein the body portion has a region of which the impurity concentration is higher than that of the surface portion within the body portion.

4. The manufacturing method for a semiconductor device according to claim 1, wherein the semiconductor device further comprises a MOS transistor for a logic circuit that is formed within a well of the second conductive type, and the well of the second conductive type is formed simultaneously with the body portion.

5. The manufacturing method for a semiconductor device according to claim 1, wherein the semiconductor device further comprises a high voltage MOS transistor which has a diffusion layer for relieving an electrical field of a source or a drain of the second conductive type, and a channel of the second conductive type, and the body portion is formed simultaneously with the diffusion layer for relieving the electrical field of the source or the drain of the MOS transistor.

6. The manufacturing method for semiconductor device according to claim 1, wherein an annealing process is carried out simultaneously on the body portion and the diffusion layers after the step (c) and before the step (d).

7. The manufacturing method for a semiconductor device according to claim 2, wherein the annealing process is carried out at a temperature in a range from 700° C. to 900° C.

8. A semiconductor device comprising:
a body portion of a DMOS of a second conductive type which is formed in a predetermined region of a well of a first conductive type that is formed in a main surface of a semiconductor substrate;
a gate dielectric film which is formed on the semiconductor substrate;
a gate electrode which is formed on the gate dielectric film so as to cross an end of the body portion;
diffusion layers of the first conductive type which are formed in the main surface of the semiconductor substrate on both sides of the gate electrode, provided that at least one of the diffusion layers is formed within the body portion;
a contact layer of the second conductive type which is formed within the body portion and of which the impurity concentration is higher than that of the body portion; and
the body portion including a region where the difference in the impurity concentration between the body portion and the well in the depth direction is greater than the difference in the impurity concentration between the body portion and the well in the surface of the semiconductor substrate.

9. The semiconductor device according to claim 8, wherein the body portion includes a region of which the impurity concentration is 1.5 times higher or more, than the impurity concentration of the body portion in the surface of the semiconductor substrate in the depth direction.

10. The semiconductor device according to claim 8, wherein the diffusion layers on both sides of the gate electrode are a source and a drain.

11. The semiconductor device according to claim 8, wherein the diffusion layers on both sides of the gate electrode are either a source or a drain, and either a drain or a source, whichever is different from the diffusion layers, is provided in a rear surface of the semiconductor substrate.
